(19) United States
(12) Patent Application Publication
(10) Pub. No.: US 2021/0333458 A1
(43) Pub. Date: Oct. 28, 2021

(54) POLARIZER SHEET, DISPLAY PANEL AND DISPLAY DEVICE

(71) Applicant: Wuhan China Star Optoelectronics Technology Co., Ltd., Wuhan (CN)

(72) Inventors: Junfeng HUANG, Wuhan (CN); Bocai CHEN, Wuhan (CN)

(73) Assignee: Wuhan China Star Optoelectronics Technology Co., Ltd., Wuhan (CN)

(21) Appl. No.: 16/611,482

(22) PCT Filed: Sep. 24, 2019
(86) PCT No.: PCT/CN2019/107417

§ 371 Date: Nov. 7, 2019

(30) Foreign Application Priority Data
Apr. 29, 2019 (CN) 201910354251.2

(51) Int. Cl. G02B 5/30; H01L 27/32; G02F 1/1362; H01L 51/52

(52) U.S. Cl. CPC G02B 5/3058; G02B 5/305; H01L 51/5293; G02F 1/136222; H01L 27/322

(57) ABSTRACT

A polarizer sheet, a display panel and a display device are provided. The polarizer sheet includes a supporting layer, a polarizing layer, and an electrically conductive layer. The display panel includes the polarizer sheet, a color filter substrate, an array substrate, and a silver adhesive layer. The display device includes the display panel. The invention reduces a used amount of silver adhesive, reduces cost, increases contacting area between the polarizer sheet and the color filter substrate, and increases a proportion of a screen, so that the polarizer sheet can be applied to a full screen narrow border mobile phone.

### FIELD

The present disclosure relates to display panel technologies, and more particularly, to a polarizer sheet, a display panel and a display device.

### BACKGROUND

Liquid crystal display or organic light emitting diode (OLED) display has been widely used and accepted by market because of its advantages of lightness, thinness and good display effect. However, the market demand for thinner screens. In recent years, the continuous demand for thickness reduction of a whole machine by mobile phone manufacturers has made it to continuously reduce a thickness of a mobile phone screen (TFT LCD\OLED). A polarizer is also one of main structures of the screen, and a thickness of a body of the polarizer is required to be thinner and thinner while still maintaining its normal function, thereby reducing an overall thickness of the screen.

Industries have continuously researched and developed to gradually reduce an overall thickness of a polarizing plate of one bias from about 200 μm to 100 μm by reducing a thickness of a cellulose triacetate (TAC) and a polyvinyl alcohol (PVA). Later, each polarizer supplier began exploring further reductions in thickness by replacing the TAC with a thinner cycloolefin polymer (COP) material. What is more, by reducing the TAC layer, the overall thickness is reduced to about 80 μm. Considering the problems of support strength, shrinkage, and reliability, the polarizer (POL) with reduced TAC layer is mostly used in a lower polarizing plate with a high-reflection film, so that the overall thickness of an upper polarizing plate and the lower polarizing plate can be reduced to about 160 μm.

With rapid development of panel industries, a narrow frame display has become the development trend in the next few years. At present, narrow-border mobile phones mainly use high-resistance film with silver adhesive for electrostatic discharge (ESD) protection, and reserve more display areas for design. A current conductive polarizer needs to be coated with a long silver adhesive line in a silver paste process, and a large amount of silver adhesive increases a cost of the product (if a method of silver adhesive point is used, a contacting area between an electrically conductive adhesive of the polarizer and the silver adhesive is smaller. It is prone to poor contact to result in ESD damage during a later use of the product.) On the other hand, the silver glue line occupies part of a border area. If the border of product is narrow, there is a signal short risk. Therefore, full screen products mainly use the high-resistance films. However, due to high cost of the high-resistance films, each panel costs a few more dollars, which reduces the competitiveness of products.

As shown in FIG. 1, the conventional panel includes an array substrate 10, a color filter substrate 20, a polarizer sheet 30, and a silver adhesive layer 40.

The color filter substrate 20 is disposed on an upper surface of the array substrate 10, the polarizer sheet 30 is disposed on an upper surface of the color filter substrate 20, and the silver adhesive layer 40 is disposed on a side of the polarizer sheet 30 and the color filter substrate 20 and extended to the upper surface of the array substrate 10. A size of the polarizer sheet 30 is smaller than a size of the color filter substrate 20 for reserving space for the silver adhesive layer 40, which makes the screen ratio smaller, and is not suitable for the pursuit of full screen.

Therefore, prior art has drawbacks and is in urgent need of improvement.

### SUMMARY

In view of the above, the present disclosure provides a polarizer sheet, a display panel and a display device to solve technical issues about high cost of an electrically conductive polarizer sheet using a silver adhesive line and bad contact between the electrically conductive polarizer sheet and the silver adhesive line.

In order to achieve above-mentioned object of the present disclosure, one embodiment of the disclosure provides a polarizer sheet including a supporting layer with a first surface and a second surface opposite to the first surface, a polarizing layer disposed on the first surface of the supporting layer, and an electrically conductive layer disposed on a surface of the polarizing layer opposite to another surface of the polarizing layer facing the supporting layer.

In one embodiment of the disclosure, the polarizer sheet further comprises a pressure sensitive adhesive disposed on the second surface of the supporting layer.

In one embodiment of the polarizer sheet, the polarizing layer is made of a material including polyvinyl alcohol.

In one embodiment of the polarizer sheet, the supporting layer is made of a material including cycloolefin polymer.

In one embodiment of the polarizer sheet, the electrically conductive layer is made of a mixed material including electrically conductive material, cellulose triacetate, and heat curing material.

Furthermore, another embodiment of the disclosure provides a display panel including the polarizer sheet abovementioned.

In one embodiment of the disclosure, the display panel further including a color filter substrate, an array substrate, and a silver adhesive layer. The color filter substrate is disposed on the surface of the polarizer sheet that a pressure sensitive adhesive is disposed thereon. The array substrate is disposed on a surface of the color filter substrate opposite to another surface of the color filter substrate facing the polarizer sheet. An electrically conductive pad is disposed on a surface of the array substrate opposite to another surface of the array substrate facing polarizer sheet. The silver adhesive layer is disposed between a surface of the electrically conductive layer of the polarizer sheet and a surface of the electrically conductive pad of the array substrate.

In one embodiment of the display panel, a shape of the polarizer sheet is the same with a shape of the color filter substrate, and a side of the polarizer sheet is aligned with a side of the color filter substrate.

In one embodiment of the display panel, a shape of the array substrate is the same with a shape of the color filter substrate, and a size of the array substrate is greater than a size of the color filter substrate.

In one embodiment of the display panel, a middle of the silver adhesive layer is disposed at a side of the polarizer sheet and a side of the color filter substrate.

Furthermore, another embodiment of the disclosure provides a display device including the display panel abovementioned.

In comparison with the prior art, one embodiment of the disclosure provides the electrically conductive layer is a top layer of the polarizer sheet, and the silver adhesive layer is applying on the electrically conductive layer directly. There is no need to reserve space of the color filter substrate for silver adhesive layer. The size of the polarizer sheet is the same with the size of the color filter substrate. The proportion of screen is increase. The polarizer sheet is suitable for full screen narrow border panel. The invention applies the silver adhesive layer by adhesive dot dispensing to reduce difficulty of processes, save using amount of silver adhesive, reduce product cost, and enhance product competitiveness.

### BRIEF DESCRIPTION OF DRAWINGS

FIG. 1 is a schematic view of a structure of a display panel according to prior art.

FIG. 2 is a schematic view of a structure of a display panel according to an embodiment of the invention.

FIG. 3 is a schematic top view of a structure of a display panel according to an embodiment of the invention.

FIG. 4 is a schematic view of a structure of a display device according to an embodiment of the invention.

Reference numbers of the present disclosure are as follows:
10: array substrate, 20: color filter substrate, 30: polarizer sheet, 310: electrically conductive layer, 320: supporting layer, 330: polarizing layer, 340: protective layer, 40: silver adhesive layer, 1: array substrate, 2: color filter substrate, 3: polarizer sheet, 31: pressure sensitive adhesive, 32: supporting layer, 33 polarizing layer, 34: electrically conductive layer, 4: silver adhesive layer, 100: display panel, 200: backlight module.

### DETAILED DESCRIPTION

The following description of the embodiments is provided by reference to the following drawings and illustrates the specific embodiments of the present disclosure. Directional terms mentioned in the present disclosure, such as “up,” “down,” “top,” “bottom,” “forward,” “backward,” “left,” “right,” “inside,” “outside,” “side,” “peripheral,” “central,” “horizontal,” “peripheral,” “vertical,” “longitudinal,” “axial,” “radial,” “uppermost” or “lowermost,” etc., are merely indicated the direction of the drawings. Therefore, the directional terms are used for illustrating and understanding of the application rather than limiting thereof.

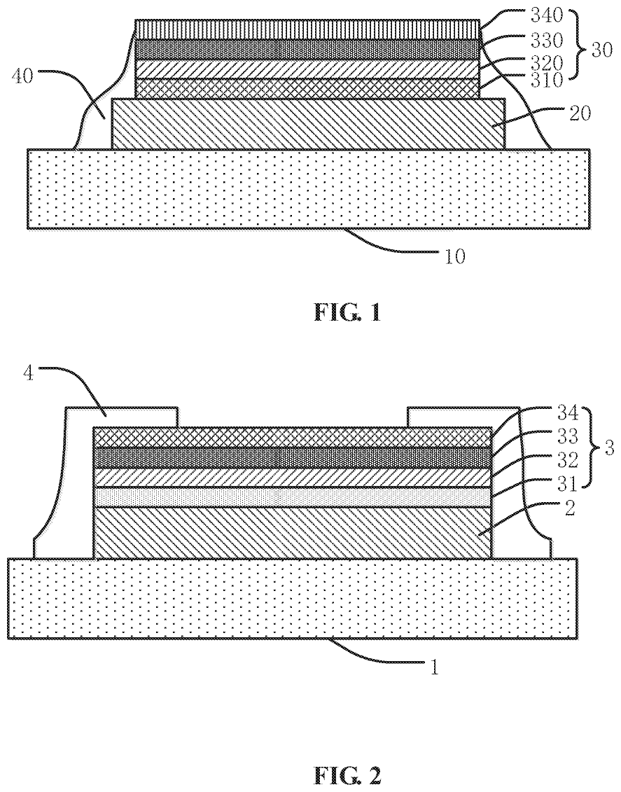

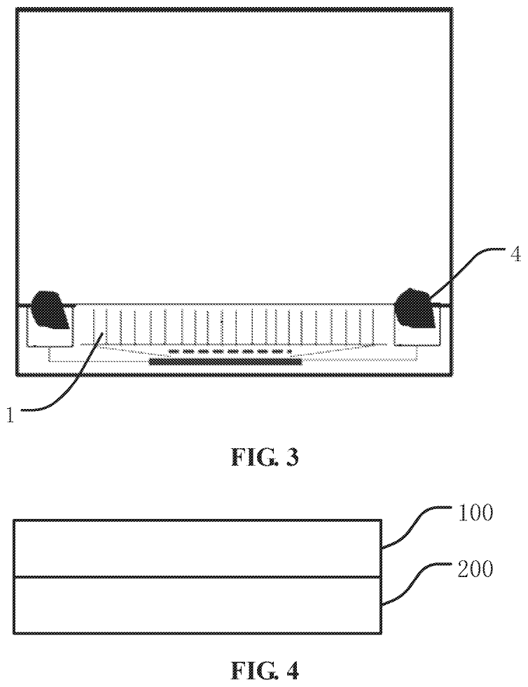

Referring to FIGS. 2 and 3, one embodiment of the disclosure provides a display panel including an array substrate 1, a color filter substrate 2, a polarizer sheet 3, and a silver adhesive layer 4.

The color filter substrate 2 is disposed on the array substrate 1. A size of the color filter substrate 2 is smaller than a size of the array substrate 1 to facilitate subsequent coating of silver adhesive layer 4. A shape of the color filter substrate 2 is the same with a shape of the array substrate 1. Preferably, the shape is a rectangle in this embodiment.

The polarizer sheet 3 includes a supporting layer 32, a polarizing layer 33, and an electrically conductive layer 34. The principle of the polarizer sheet is that when iodine molecules are arranged in the same direction, an asymmetric electron density is generated, so polarization light absorption coefficients in different directions are different. If the polarization direction of the light and the long axis of the iodine molecular chain remain at 90°, then polarized light can pass. Conversely, intensity of transmitted light will continue to decrease, even to complete obscuration. Therefore, it can be concluded that the long chain of the iodine molecule has good polarization.

The supporting layer 32 is made of a material including cycloolefin polymer (COP). The COP is a rapidly developing optical material in recent years, and its optical characteristics are higher than that of a conventional supporting layer material, cellulose triacetate (TAC). COP far exceeds TAC in mechanical characters, temperature resistance and weather resistance, so the supporting layer 3 in this embodiment uses COP

One side of the supporting layer 32 of the polarizer sheet 3 adheres to the color filter substrate 2 by a pressure sensitive adhesive 31. The pressure sensitive adhesive 31 is made of an acrylic rubber. The pressure sensitive adhesive 31 has good removability and strong holding force, and ensures a good fit of the polarizer sheet 3 and the color filter substrate 2. A shape of the polarizer sheet 3 is the same with a shape of the color filter substrate 2. Preferably, the shape is a rectangle in this embodiment. A size of the polarizer sheet 3 is the same with a size of the color filter substrate 2. A side of the polarizer sheet 3 is aligned with a side of the color filter substrate 2.

The polarizing layer 33 is a core layer of the polarizer sheet 3 and is disposed on the supporting layer 32. The polarizing layer 33 is made of a material including polyvinyl alcohol (PVA). The polarizing layer 33 has good transparency and polarizing characteristics. The polarizing layer 33 has good affinity with iodine molecules, and has high orientation when stretched. PVA has good water solubility, and therefore the water repellency of the polarizing layer 33 is compared weak. Other film layers with good waterproof properties are required to protect the polarizing layer 33.

The electrically conductive layer is disposed on the polarizing layer 33. The conductive layer 34 is a film layer made of an electrically conductive material melted into a protective material. The protective material is TAC. The electrically conductive material includes an organic electrically conductive polymer, an inorganic metal oxide, etc. The electrically conductive material is melted into the protective material to form a mixed material, and the mixed material is subjected to surface harden casting (HC) to form an electrically conductive layer 34.

The electrically conductive layer 34 is disposed on the top of the polarizer sheet 3, and does not affect the polarizing performance of the polarizer sheet 3. The electrically conductive principle is the same as that of the existing polarizer sheet, and does not affect the electrically conductive performance of the polarizer.

The PVA will quickly deform and shrink in a warm environment, and the TAC has a function to prevent retraction of the PVA, and therefore, the electrically conductive layer 34 is used to protect the polarizing layer. 33.

The electrically conductive material is melted into the protective material to form a conductive layer having both electrically conductive and protective effects. A thickness of the polarizer sheet is reduced while ensuring the quality of the polarizer sheet, and a thickness of a panel can be further reduced.

The size of the polarizer sheet 3 is the same with the size of the color filter substrate 2. It increases contacting area between the polarizer sheet 3 and the color filter substrate 2, and increases a proportion of a screen, so that the polarizer sheet can be applied to a full screen narrow border panel.

One end of the silver adhesive layer 4 is extended to a top surface of the polarizer sheet 3, and another end of the silver adhesive layer 4 is extended to an electrically conductive pad (not shown) on a top surface of the array substrate 1. A middle of the silver adhesive layer 4 is disposed at a side of the polarizer sheet 3 and a side of the color filter substrate 2. The silver adhesive layer 4 adheres the color filter substrate 2 with the array substrate 1. Main components of the silver adhesive layer 4 are a matrix resin, a silver powder, an additive, and the like. The silver adhesive layer 4 is a special adhesive having both adhesive properties and electrical conductivity. Therefore, the silver adhesive layer 4 bonds the polarizer sheet 3, the color filter substrate 2, and the array substrate 1 on one hand, and provides good electrical conductivity on the other hand. During assembly process, a mobile phone generates static electricity through various machines. When one tears a protective film from the mobile phone, static electricity is generated. In the process of using the mobile phone and in the manual assembly process, human body also generates static electricity to cause electrostatic breakdown. The silver adhesive layer 4 releases the various static electricity generated as described above through the electrically conductive pads on the array substrate 1.

In comparison with the prior art, one embodiment of the disclosure provides the electrically conductive layer to be a top layer of the polarizer sheet without affect the polarizing performance and the electrically conductive performance, and the silver adhesive layer is applying on the electrically conductive layer directly. There is no need to reserve space of the color filter substrate for silver adhesive layer. The size of the polarizer sheet is the same with the size of the color filter substrate. The proportion of screen is increase. The polarizer sheet is suitable for full screen narrow border panel. The invention applies the silver adhesive layer by adhesive dot dispensing to reduce difficulty of processes, save using amount of silver adhesive, reduce product cost, and enhance product competitiveness.

Referring to FIG. 4, one embodiment of the disclosure further disclosure a display device including a display panel 100 and a backlight module 200. The display panel 100 is one of the abovementioned display panel. The backlight module 200 includes direct type backlight module and side type backlight module. The disclosure of these embodiment is similar to the disclosure abovementioned and will not described in detail herein.

The present disclosure has been described by the above embodiments, but the embodiments are merely examples for implementing the present disclosure. It must be noted that the embodiments do not limit the scope of the invention. In contrast, modifications and equivalent arrangements are intended to be included within the scope of the invention.

What is claimed is:

1. A polarizer sheet, comprising:
a supporting layer with a first surface and a second surface opposite to the first surface;
a polarizing layer disposed on the first surface of the supporting layer; and
an electrically conductive layer disposed on a surface of the polarizing layer opposite to another surface of the polarizing layer facing the supporting layer.

2. The polarizer sheet according to claim 1, further comprising a pressure sensitive adhesive disposed on the second surface of the supporting layer.

3. The polarizer sheet according to claim 1, wherein the polarizing layer is made of a material comprising polyvinyl alcohol.

4. The polarizer sheet according to claim 1, wherein the supporting layer is made of a material comprising cycloolefin polymer.

5. The polarizer sheet according to claim 1, wherein the electrically conductive layer is made of a mixed material comprising electrically conductive material, cellulose triacetate, and heat curing material.

6. A display panel, comprising the polarizer sheet according to claim 1.

7. The display panel according to claim 6, further comprising:
a color filter substrate, disposed on the surface of the polarizer sheet that a pressure sensitive adhesive is disposed thereon;
an array substrate disposed on a surface of the color filter substrate opposite to another surface of the color filter substrate facing the polarizer sheet, wherein an electrically conductive pad is disposed on a surface of the array substrate opposite to another surface of the array substrate facing polarizer sheet; and
a silver adhesive layer disposed between a surface of the electrically conductive layer of the polarizer sheet and a surface of the electrically conductive pad of the array substrate.

8. The display panel according to claim 7, wherein a shape of the polarizer sheet is the same with a shape of the color filter substrate; and
wherein a side of the polarizer sheet is aligned with a side of the color filter substrate.

9. The display panel according to claim 7, wherein a shape of the array substrate is the same with a shape of the color filter substrate; and
wherein a size of the array substrate is greater than a size of the color filter substrate.

10. The display panel according to claim 7, wherein a middle of the silver adhesive layer is disposed at a side of the polarizer sheet and a side of the color filter substrate.

11. A display device, comprising the display panel according to claim 6.
